(19) United States
(12) Patent Application Publication
(10) Pub. No.: US 2010/0025778 A1
(43) Pub. Date: Feb. 4, 2010

(54) TRANSISTOR STRUCTURE AND METHOD OF MAKING THE SAME

(76) Inventors: Chao-Sung Lai, Tao-Yuan City (TW); Hsing-Kan Peng, Hsinchu County (TW); Shian-Jyh Lin, Taipei County (TW); Chung-Yuan Lee, Tao-Yuan City (TW)

Correspondence Address: NORTH AMERICA INTELLECTUAL PROPERTY CORPORATION, P.O. BOX 506, MERRIFIELD, VA, 22116, US

(21) Appl. No.: 12/183,074

(22) Filed: Jul. 31, 2008

(51) Int. Cl. H01L 29/78; H01L 21/336

(52) U.S. Cl. 257/407; 438/301; 257/E21.409; 257/E29.255

(57) ABSTRACT

A transistor includes a gate structure of HfMoN. The work function of the gate structure can be modulated by doping the HfMoN with dopants including nitride, silicon or germanium. The gate structure of HfMoN of the present invention is applicable to PMOS, NMOS or CMOS transistors.

### BACKGROUND OF THE INVENTION

1. Field of the Invention

The present invention relates to a transistor structure and a method for forming the same. More particularly, the present invention relates to a transistor with an HfMoN layer serving as the control gate.

2. Description of the Prior Art

Complementary metal-oxide-semiconductors (CMOS) are a major class of integrated circuits. According to the polarity of the CMOS's channel, the CMOS can be divided into P-type and N-Type, i.e. PMOS and NMOS. CMOS technology is used in chips such as microprocessors, microcontrollers, static RAM, and other digital logic circuits. In addition, a CMOS consumes power only during its switching on or off time. Therefore power is saved and heat generation is reduced during the operation of the CMOS.

Functionally speaking, PMOS and NMOS each have different threshold voltages, which are determined by the difference of the work function of the gate and the channel material. Two different metals can be utilized as the gate materials.

Because two layers of different metals are required to be the gate material, the two layers are formed separately. For example: a first gate electrode material layer is entirely formed on a substrate, later, a selective etching is performed based on a well defined patterned hard mask, then a second gate electrode material layer fills the space defined by the selective etching, and finally the surfaces of the first gate electrode material layer and the second gate electrode material layer are planarized to complete the fabrication.

Another example of fabricating the gate with two layers of different metals is described herein: a sacrificial layer is entirely formed on a substrate top face, later, the sacrificial layer is selectively removed to allow a first gate electrode material to fill in gaps defined by the removal of the sacrificial layer, and then the sacrificial layer is completely removed to allow a second gate electrode material layer to fill in gaps from the removal of the sacrificial layer to complete the fabrication.

No matter which method is used, a selective etching must be performed to form different metal layers for respectively deciding the threshold voltages of the PMOS and NMOS. It is clear that the concept of forming the first gate electrode material layer first followed by the etching to form the second gate electrode is both complex and troublesome and does not meet the demand of simplicity pursued by the industry.

### SUMMARY OF THE INVENTION

Therefore, a simple and convenient method for forming a transistor with different threshold voltages is provided in the present invention.

According to a preferred embodiment of the present invention, a method of forming a transistor comprises the steps of: a substrate having a first dielectric layer on top of the substrate surface is provided. Than, a conductive layer is formed on the first dielectric layer, wherein the conductive layer comprises at least hafnium, molybdenum and nitrogen. Next, a second dielectric layer is formed on top of the conductive layer. After that, the second dielectric layer, the conductive layer and the first dielectric layer are patterned to form a gate structure on the substrate. Finally, a source/drain doping region is formed in the substrate at a side of the gate structure.

According to another preferred embodiment of the present invention, a method of forming a transistor, comprises steps of: first, a substrate having a first dielectric layer on top of the substrate surface is provided. Next, a conductive layer is formed on the first dielectric layer, wherein the conductive layer comprises hafnium, molybdenum and nitrogen. Than, the conductive layer is doped. After that, a second dielectric layer is formed on top of the conductive layer. Latter, the second dielectric layer, the conductive layer and the first dielectric layer are patterned to form a gate structure on the substrate. Finally, a source/drain doping region is formed in the substrate at a side of the gate structure.

According to another preferred embodiment of the present invention, a transistor structure comprises: a substrate, a gate structure positioned on the substrate, wherein the gate structure comprises: a gate dielectric layer formed on the surface of the substrate and a conductive layer formed on the gate dielectric layer, wherein the conductive layer at least comprises hafnium, molybdenum and nitrogen. The transistor structure further comprises a source/drain doping region formed in the substrate and adjacent to the gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a method of making transistors according to a first embodiment of the present invention.

FIG. 7 to FIG. 1 3 depict a method of making transistors according to a second embodiment of the present invention.

### DETAILED DESCRIPTION

A method of making transistors, such as PMOS, NMOS and CMOS is provided in the present invention.

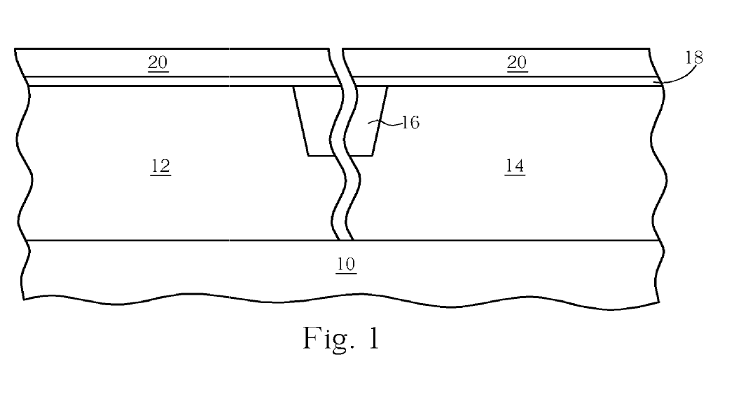

FIG. 1 to FIG. 6 depict a method of making transistors according to a first embodiment of the present invention.

FIG. 1 shows a substrate 10 comprising a first doping well 12, a second doping well 14 and an STI structure 16 composed of insulating materials. A gate dielectric layer 18 is formed on top of the substrate surface. The substrate 10 may be a P-type substrate, an N-type substrate or a silicon-on-insulator (SOI) substrate. The gate dielectric layer 18 may be composed of oxide, nitride, oxy-nitride or any material having a high dielectric constant. According to a preferred embodiment of the present invention, the gate dielectric layer may be SiN, SiON compounds, HfSiON, ZrO₂ or HfO₂.

Next, a conductive layer comprising at least hafnium, molybdenum and nitrogen, such as an HfMoN layer 20, is formed on the gate dielectric layer 18, wherein the method of forming the HfMoN layer 20 comprises forming the HfMoN layer 20 in a nitrogen-containing environment by a co-sputtering physical vapor deposition process or a chemical vapor deposition process. According to a preferred embodiment of the present invention, the HfMoN layer 20 is formed by the co-sputtering physical vapor deposition process. By taking the Hf and Mo as targets, the Hf and Mo targets are bombarded by inert gases such as argon with 50˜500W power in a nitrogen-containing environment. In this way, the HfMoN layer 20 can be formed on the surface of the gate dielectric layer 18. In addition, the target can be Hf—Mo alloy, and the HfMoN layer 20 can be formed by a conventional sputtering process.

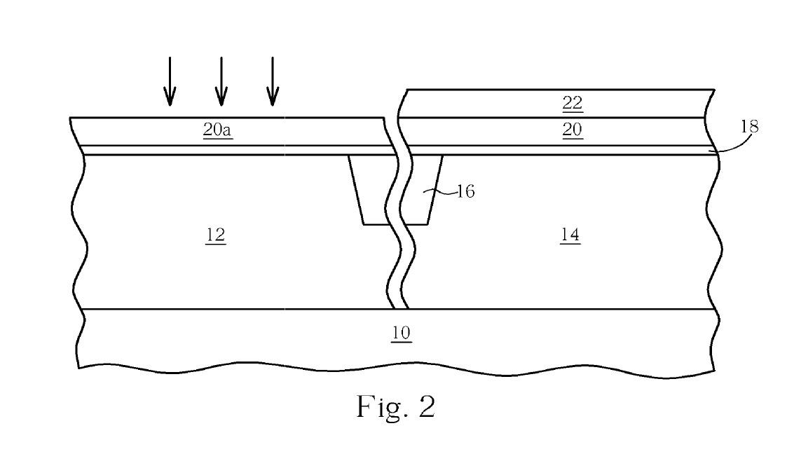

As shown in FIG. 2, the HfMoN layer 20 is covered by a photoresist 22, wherein the HfMoN layer 20 covered by the photoresist 22 is positioned on the second doping well 14. Then, the HfMoN layer 20 positioned on the first doping well 12 is doped in order to modulate the work function of the HfMoN layer 20. Then the HfMoN layer 20 positioned on the first doping well 12 after doping forms an HfMoN layer 20a. The dopant doped in the HfMoN layer 20a can be N, Si, Ge, Mo, Hf or any element which can change the work function. In addition, the method of doping the HfMoN layer 20 is not limited to an ion implantation process, and a diffusion process can be used as well. Furthermore, if the dopant doped in the HfMoN layer 20 is nitrogen, the plasma nitridation process can also be used to dope the HfMoN layer 20. Then the photoresist 22 is removed.

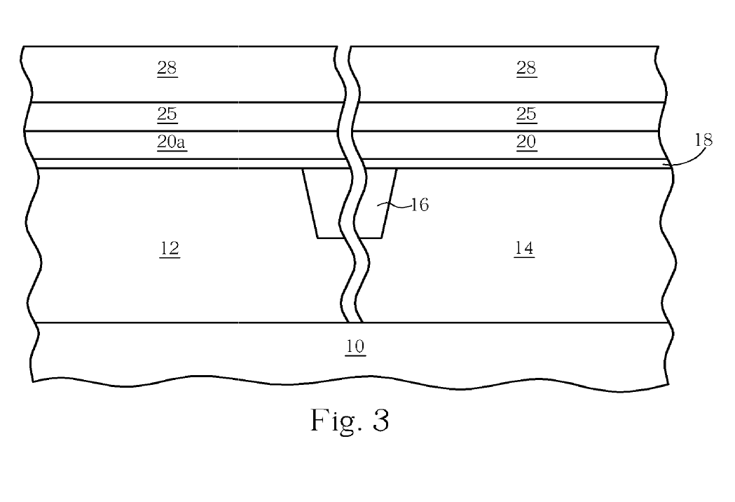

As shown in FIG. 3, a metal layer 25 is formed on the HfMoN layer 20, 20a, wherein the metal layer 25 comprises HfN, MoN, TiN, TaN, WN, W, Al, AlN, Pt, Au or any combination thereof. It is worth noting that the metal layer 25 can be omitted optionally according to different product requirements. Then, a dielectric layer 28 is formed on the metal layer 25, wherein the dielectric layer 28 comprises silicon oxide, silicon nitride or any combination thereof. If the metal layer 25 is omitted, the dielectric layer 28 will be positioned directly on the HfMoN layer 20, 20a.

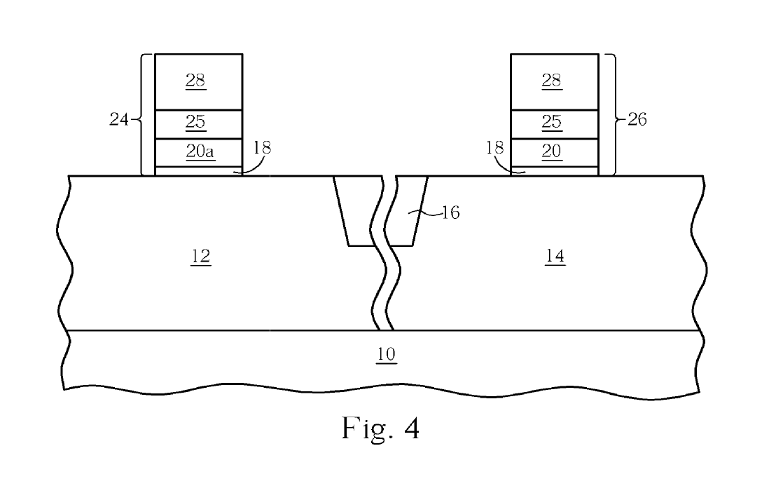

As shown in FIG. 4, a portion of the dielectric layer 28, the metal layer 25, the HfMoN layer 20, 20a and the gate dielectric layer 18 are patterned to form a first transistor gate 24 and a second transistor gate 26.

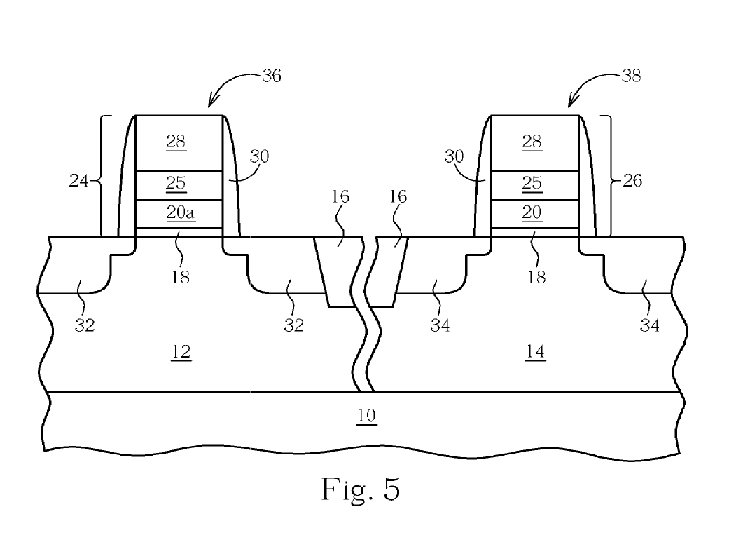

As shown in FIG. 5, a spacer 30 is formed on the sidewall of the first transistor gate 24 and the sidewall of the second transistor gate 26. Then, a first source/drain doping region 32 and a second source/drain doping region 34 are formed in the substrate positioned at two sides of the first transistor gate 24 and the second transistor gate 26, respectively, wherein the first source/drain doping region 32 and the second source/drain doping region 34 may be formed by halo implantation or lightly doped drain (LDD) implantation. Now, a first transistor 36 and a second transistor 38 are finished. According to a preferred embodiment of the present invention, the first transistor 36 may be a PMOS or NMOS and the second transistor 38 may be a PMOS or NMOS.

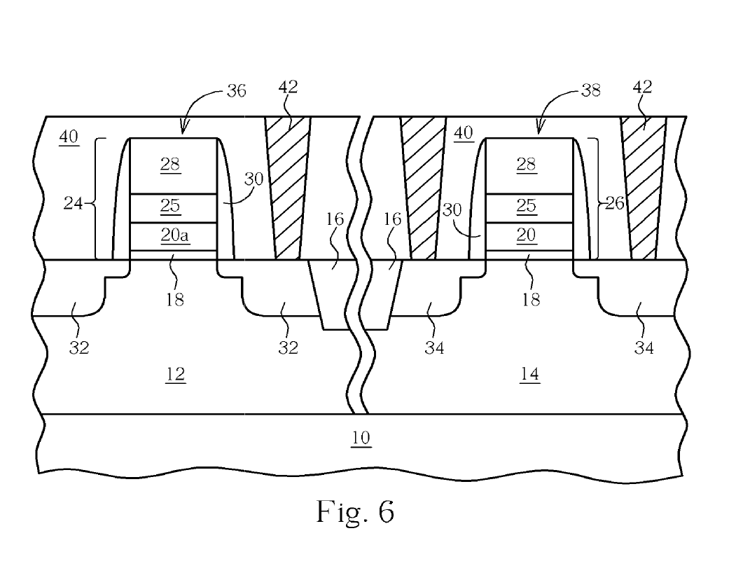

As shown in FIG. 6, an interlayer dielectric layer 40 is formed on the first transistor 36 and the second transistor 38. Next, a plurality of contact holes is formed in the interlayer dielectric layer 40 to partially expose the source/drain doping region 32. Then, a plurality of contact plugs 42 is formed in the contact holes of the interlayer dielectric layer 40 by an etching and deposition process. Contact plugs 40 contact the first source/drain doping region 32 and the second source/drain doping region 34 electrically, wherein the method of forming the contact plugs 40 comprises an atomic layer deposition (ALD) process, a physical vapor deposition process and a chemical vapor deposition process. In addition, contact plugs 40 may be composed of Ti, TiN, W, Cu or any combination thereof.

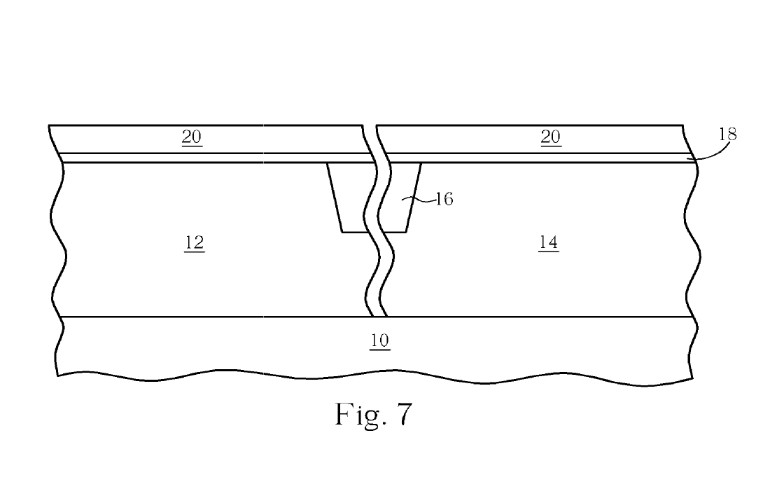

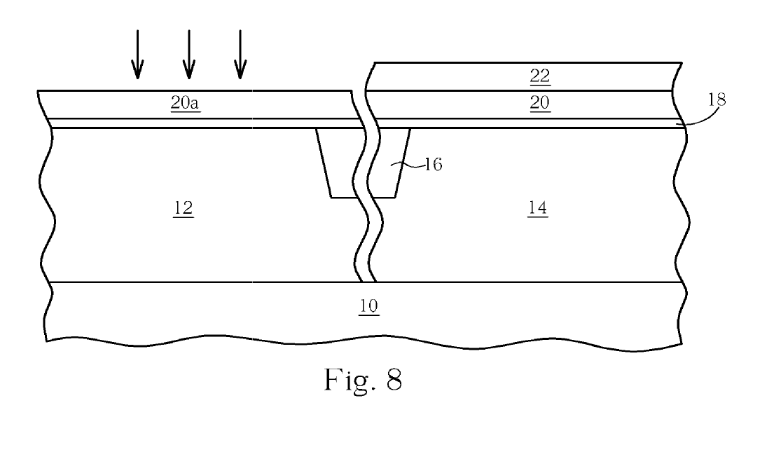

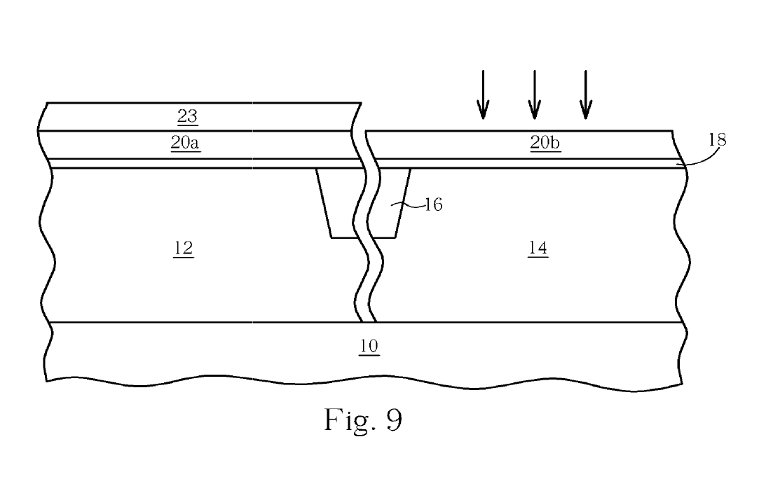

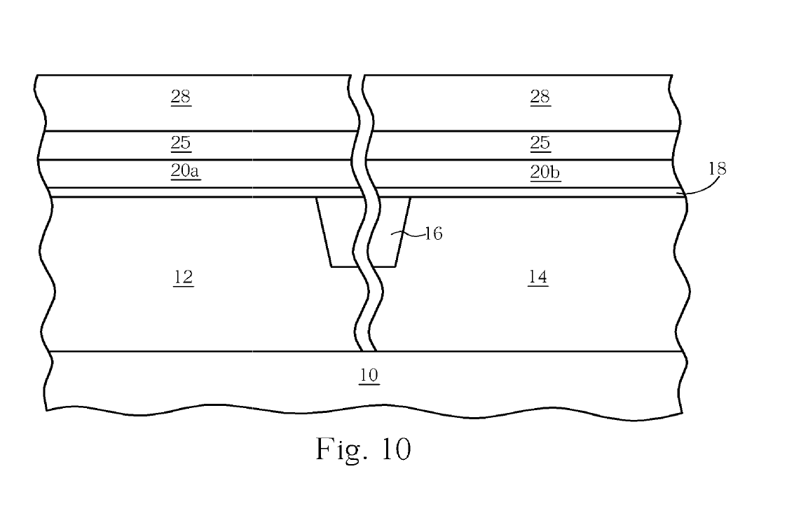

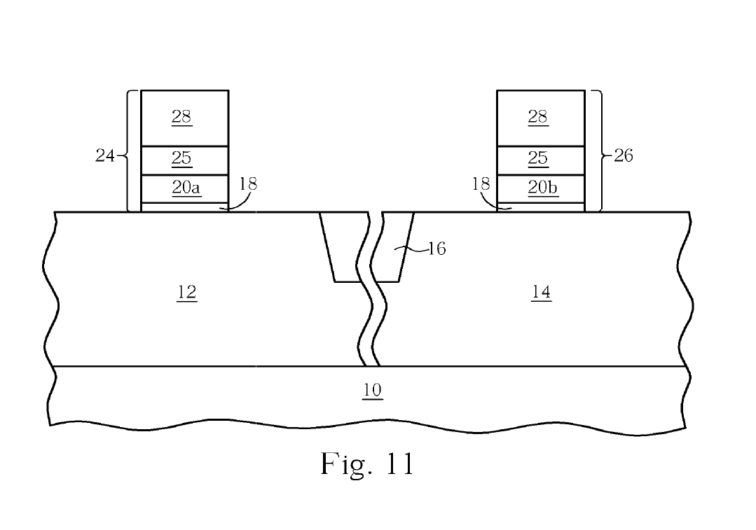

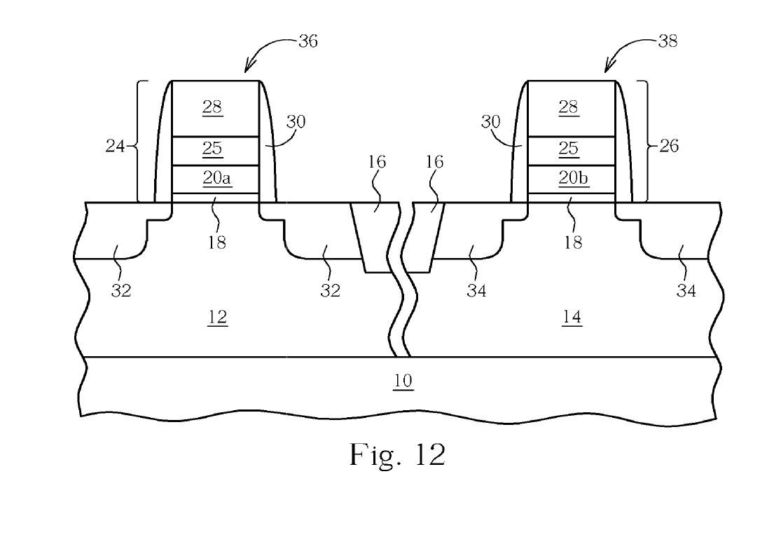

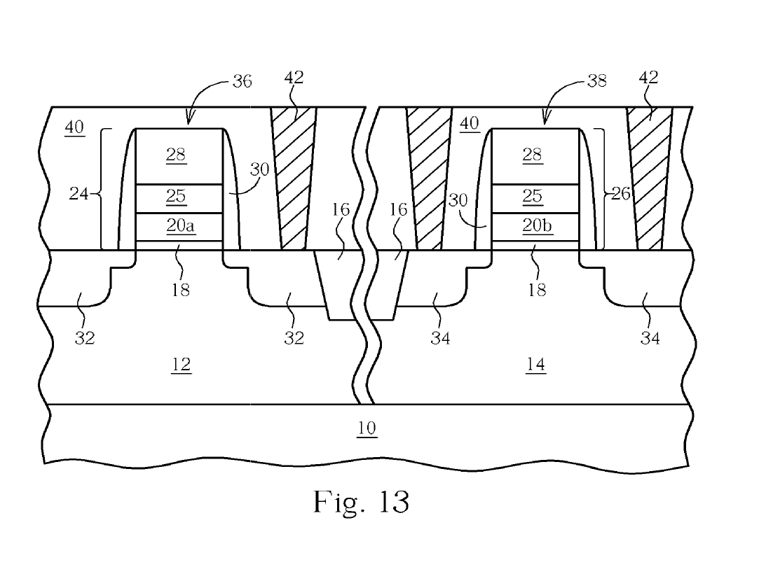

FIG. 7 to FIG. 13 depict a method of making transistors according to a second embodiment of the present invention. To simplify the illustration, elements with the same function will use the same numerals as the first embodiment. The main fabricating process of the second embodiment is the same as that of the first embodiment. The difference is that the HfMoN layer 20 positioned on the first doping well 12 and the HfMoN layer 20 positioned on the second doping well 14 are both doped with dopant in the second embodiment of the present invention.

FIG. 7 shows a substrate 10 comprising a first doping well 12, a second doping well 14 and an STI structure 16 composed of insulating materials. A gate dielectric layer 18 is formed on top of the substrate surface. Next, a conductive layer comprising at least hafnium, molybdenum and nitrogen, such as an HfMoN layer 20, is formed on the gate dielectric layer 18.

As shown in FIG. 8, a photoresist 22 covers the HfMoN layer 20, wherein the HfMoN layer 20 covered by the photoresist 22 is positioned on the second doping well 14. Then, the HfMoN layer 20 positioned on the first doping well 12 is doped in order to modulate the work function of the HfMoN layer 20. Then the HfMoN layer 20 positioned on the first doping well 12 after doping forms an HfMoN layer 20a. The dopant doped in the HfMoN layer 20a can be N, Si, Ge, Mo, Hf, any combination thereof or any elements which can change the work function. Then the photoresist 22 is removed.

As shown in FIG. 9, a photoresist 23 covers the HfMoN layer 20, wherein the HfMoN layer 20 covered by the photoresist 23 is positioned on the first doping well 12. Then, the HfMoN layer 20 positioned on the second doping well 14 is doped in order to modulate the work function of the HfMoN layer 20 positioned on the second doping well 14. Then the HfMoN layer 20 positioned on the second doping well 14 after doping forms an HfMoN layer 20b. The dopant doped in the HfMoN layer 20a can be N, Si, Ge, any combination thereof or any element which can change the work function. Then the photoresist 23 is removed. The step shown in FIG. 9 is the difference between the first embodiment and the second embodiment.

The following steps are the same as in the first embodiment. As shown in FIG. 10, a metal layer 25 is formed on the HfMoN layer 20a, 20b, wherein the metal layer 25 comprises HfN, MoN, TiN, TaN, WN, W, Al, AlN, Pt, Au or any combination thereof. It is worth noting that the metal layer 25 can be omitted optionally according to different product requirements. Then, a dielectric layer 28 is formed on the metal layer 25, wherein the dielectric layer 28 comprises silicon oxide, silicon nitride or any combination thereof. If the metal layer 25 is omitted, the dielectric layer 28 will be positioned on the HfMoN layer 20a, 20b.

As shown in FIG. 11, a first transistor gate 24 and a second transistor gate 26 are formed. As shown in FIG. 12, a spacer 30 is formed on the sidewall of the first transistor gate 24 and the sidewall of the second transistor gate 26. Then, a first source/drain doping region 32 and a second source/drain doping region 34 are formed in the substrate positioned at two side of the first transistor gate 24 and the second transistor gate 26, respectively. Now, a first transistor 36 and a second transistor 38 are finished. According to a preferred embodiment of the present invention, the first transistor 36 may be a PMOS or NMOS and the second transistor 38 may be a PMOS or NMOS.

As shown in FIG. 13, an interlayer dielectric layer 40 is formed on the first transistor 36 and the second transistor 38. Next, a plurality of contact holes is formed in the interlayer dielectric layer 40 to partially expose the source/drain doping region 32. Then, a plurality of contact plugs 42 is formed in the contact holes of the interlayer dielectric layer 40. Contact plugs 40 contact the first source/drain doping region 32 and the second source/drain doping region 34 electrically.

A first transistor structure of PMOS, NMOS and CMOS is provided according to a preferred embodiment of the present invention. As shown in FIG. 4, the transistor structure of PMOS, NMOS and CMOS comprises: a substrate 10 comprising a first doping well 12, a second doping well 14 and a STI structure 16. A first transistor 36 and a second transistor 38 are positioned on the surface of the first doping well 12 and the second doping well 14 respectively, wherein the first transistor 36 comprises a first transistor gate 24, a spacer 30 and a first source/drain doping region 32 adjacent to the first transistor gate 24 and wherein the second transistor 38 comprises a second transistor gate 26, a spacer 30 and a second source/drain doping region 24 adjacent to the second transistor gate 26. In addition, the first transistor gate 24 comprises a gate dielectric layer 18 positioned on the surface of the substrate 10, a first conductive layer comprising at least hafnium, molybdenum and nitrogen, such as an HfMoN layer 20a, positioned on the surface of the gate dielectric layer 18, a metal layer 25 positioned on the surface of the HfMoN layer 20a, and a dielectric layer 28 positioned on the surface of the metal layer 25. The second transistor gate 26 comprises the gate dielectric layer 18 positioned on the surface of the substrate 10, a second conductive layer comprising at least hafnium, molybdenum and nitrogen, such as a HfMoN layer 20, positioned on the surface of the gate dielectric layer 18, the metal layer 25 positioned on the surface of the HfMoN layer 20, and the dielectric layer 28 positioned on the surface of the metal layer 25. The HfMoN layer 20 mentioned above may comprise dopant optionally, wherein the dopant may be N, Si, Ge or any combination thereof. The metal layer 25 may be formed optionally according to different requirements.

A second transistor structure of PMOS, NMOS and CMOS according to another preferred embodiment of the present invention is also given. As shown in FIG. 12, the transistor structure of PMOS, NMOS and CMOS comprises: a substrate 10 comprising a first doping well 12, a second doping well 14 and a STI structure 16. A first transistor 36 and a second transistor 38 are positioned on the surface of the first doping well 12 and the second doping well 14 respectively, wherein the first transistor 36 comprises a first transistor gate 24, a spacer 30 and a first source/drain doping region 32 adjacent to the first transistor gate 24 and wherein the second transistor 38 comprises a second transistor gate 26, a spacer 30 and a second source/drain doping region 24 adjacent to the second transistor gate 26. In addition, the first transistor gate 24 comprises a gate dielectric layer 18 positioned on the surface of the substrate 10, a first conductive layer comprising at least hafnium, molybdenum and nitrogen, such as an HfMoN layer 20a, positioned on the surface of the gate dielectric layer 18, a metal layer 25 positioned on the surface of the HfMoN layer 20a, and a dielectric layer 28 positioned on the surface of the metal layer 25. The second transistor gate 26 comprises the gate dielectric layer 18 positioned on the surface of the substrate 10, a second conductive layer comprising at least hafnium, molybdenum and nitrogen, such as an HfMoN layer 20b, positioned on the surface of the gate dielectric layer 18, the metal layer 25 positioned on the surface of the HfMoN layer 20b, and the dielectric layer 28 positioned on the surface of the metal layer 25. The HfMoN layer 20a, 20b mentioned above may comprise dopant such as N, Si or Ge, or any combination thereof. The metal layer 25 may be formed optionally according to different requirements.

The difference between the first and the second transistor structure of the present invention is that: according to the first transistor structure, the HfMoN layer 20a in the first transistor gate 24 is formed by doping the HfMoN layer 20 in order to modulate the work function of the HfMoN layer 20. However, unlike the HfMoN layer 20a, the HfMoN layer 20 in the second transistor gate 26 maintains the original composition instead of being doped.

According to the second transistor structure, both the HfMoN layer 20a in the first transistor gate 24 and the HfMoN layer 20b in the second transistor gate 26 are doped after the HfMoN layer 20 is formed in order to modulate the work function.

It is clear that the conventional method of forming the first gate electrode material layer first followed by etching to form the second gate electrode is both complex and troublesome. The present invention provides a simplified process to form a PMOS or NMOS with different threshold voltage by taking the HfMoN as the gate, and modulating the work function by doping the HfMoN.

Those skilled in the art will readily observe that numerous modifications and alterations of the device and method may be made while retaining the teachings of the invention.

1. A method of forming a transistor, comprising the steps of:
providing a substrate having a first dielectric layer on top of the substrate surface;
forming a HfMoN layer on the first dielectric layer;
forming a second dielectric layer on top of the HfMoN layer;
patterning the second dielectric layer, the HfMoN layer and the first dielectric layer to form a gate structure on the substrate; and
forming a source/drain doping region in the substrate at a side of the gate structure such that the transistor is formed.

2. The method of forming a transistor of claim 1, further comprising the steps of:
forming an interlayer dielectric layer on the substrate to cover the gate structure and the source/drain doping region;
forming a plurality of contact holes in the interlayer dielectric layer to partially expose the source/drain doping region; and
forming a contact plug in each of the contact holes.

3. A method of forming a transistor, comprising steps of:
providing a substrate having a first dielectric layer on top of the substrate surface;
forming a HfMoN layer on the first dielectric layer;
doping the HfMoN layer;
forming a second dielectric layer on top of the HfMoN layer;
patterning the second dielectric layer, the HfMoN layer and the first dielectric layer to form a gate structure on the substrate; and
forming a source/drain doping region in the substrate at a side of the gate structure such that the transistor is formed.

4. The method of making a transistor of claim 3, further comprising:
forming an interlayer dielectric layer on the substrate to cover the gate structure and the source/drain doping region;
forming a plurality of contact holes in the interlayer dielectric layer to partially expose the source/drain doping region; and
forming a contact plug in each of the contact holes.

5. The method of forming a transistor of claim 3, wherein the dopant is selected from a group consisting of N, Si and Ge.

6. A transistor structure comprising:
a substrate;
a gate structure positioned on the substrate, wherein the gate structure comprises:
a gate dielectric layer formed on the surface of the substrate; and
a HfMoN layer formed on the gate dielectric layer; and
a source/drain doping region formed in the substrate and adjacent to the gate structure.

7. The transistor structure of claim 6, wherein the conductive layer further comprises a dopant.

8. The transistor structure of claim 7, wherein the dopant is selected from a group consisting of N, Si and Ge.

9. The transistor structure of claim 6, wherein the gate structure further comprises a metal layer positioned on the conductive layer.

10. The transistor structure of claim 9, wherein the material of the metal layer is selected from a group consisting of HfN, MoN, TiN, TaN, WN, W, Al, AlN, Pt, and Au.
